(19) United States
(12) Patent Application Publication
(10) Pub. No.: US 2015/0085069 A1
(43) Pub. Date: Mar. 26, 2015

(54) HOLOGRAPHIC IMAGE GENERATION AND RECONSTRUCTION

(71) Applicant: Empire Technology Development, LLC, Wilmington, DE (US)

(72) Inventor: Eiji Yamaichi, Tokyo (JP)

(21) Appl. No.: 14/357,769

(22) PCT Filed: Apr. 19, 2013
(86) PCT No.: PCT/US2013/037333

§ 371 Date: May 12, 2014

(51) Int. Cl. G03H 1/04; G03H 5/00; G03H 1/22; H04N 5/357; H04N 5/372

(52) U.S. Cl. CPC G03H 1/0443; H04N 5/357; H04N 5/372; G03H 1/2205; G03H 1/2286; G03H 1/2249; G03H 5/00; G03H 2001/2213; G03H 2001/2221; G03H 2001/2292; G03H 2001/2271
USPC 348/40; 359/9

(57) ABSTRACT

Technologies are generally related to holographic imaging. In some examples, techniques are described for generating a holographic image of an object using a plurality of light sources, a shutter, and an image sensor array. Each of the light sources is configured to generate a light beam using a respective wavelength in a different range. In various examples, an apparatus as described here may be configured to control the shutter to receive the light beams from the plurality of light sources and selectively pass each of the received light beams to provide a selected light beam. The apparatus may further include a beam splitter and a mirror unit configured to generate an object light beam and a reference light beam from the selected light beam. The apparatus may include an image sensor array configured to detect an image of interference caused by the reference light beam and the object light beam.

### BACKGROUND

Unless otherwise indicated herein, the approaches described in this section are not prior art to the claims in this application and are not admitted to be prior art by inclusion in this section.

Holography techniques can be used to record holograms representing images of an object and reconstruct the images from the recorded holograms. As an example of conventional holography techniques, transmission-type holography techniques can be used to generate holograms of a two-dimensional or three-dimensional object on a transmitting side, for example, by means of a CCD (charge coupled device) camera. The holograms can be transmitted to a receiving side device (e.g., a holographic television set) in the form of video signals. On the receiving side device, the holograms can be reproduced and displayed on a high-definition liquid crystal display (LCD) panel constituted of pixels having a resolution of the order of the optical diffraction limit, based on fringe patterns contained in the received video signals. In particular, the hologram can be formed by irradiating a reconstruction light that readily causes interference, e.g., irradiating coherent light emitted from a laser light source, on the fringe patterns displayed on one side of the display panel. The irradiation of the reconstruction light on the fringe patterns causes diffraction in the fringe patterns, such that a user can observe the diffracted light as holographic images emitted from the other side of the display panel.

To reproduce a color holographic image, the receiving side device may be configured to obtain a color image by reproducing interference fringe patterns of individual colors (e.g., red, green and blue) on a LCD panel in a time-division manner based on the color video signals. Such a device may employ a so-called field sequential color system. In order to obtain a color image in the field sequential color system, the fields of individual colors must be switched at a very high rate corresponding to no more than 1 to 5 milliseconds per field. However, the present disclosure recognizes that the response rate of such a conventional LCD (e.g., using nematic liquid crystal) is typically a few milliseconds, which may not be suitable for performing switching operation at such a high rate as used in the field sequential color system.

### SUMMARY

Technologies are generally described for generating color holographic images and reconstructing the color holographic images.

Various example apparatus described herein may be configured to generate a holographic image of an object. An example apparatus may include a plurality of light sources, a shutter, a beam splitter, a mirror unit, an image sensor array, and a video signal generator unit. Each of the light sources may be configured to generate a light beam corresponding to a wavelength in a different range. The shutter may be configured to receive the light beams from the plurality of light sources and selectively pass each of the received light beams in turn to provide a selected light beam. The beam splitter may be configured to split the selected light beam into a first light beam and a second light beam. Also, the beam splitter may be further configured to irradiate the first light beam on the object such that at least part of the first light beam may be scattered by the object to generate an object light beam. The mirror unit may be configured to receive the second light beam from the beam splitter, and reflect at least part of the second light beam to generate a reference light beam. The image sensor array may be configured to receive the reference light beam and the object light beam, and also configured to detect an image of interference caused by the reference light beam and the object light beam. The video signal generator unit may be configured to convert the detected image into an image signal associated with each of the plurality of light sources.

In some examples, a holographic image reconstruction apparatus is described such as any example apparatus described herein that may be adapted to reconstruct a holographic image of an object. The apparatus may be adapted to utilize a receiver unit configured to receive an input signal representative of a hologram of the object. The apparatus may be further adapted to utilize a virtual image light source configured to generate a virtual image light beam responsive to the input signal, and a scan mirror configured to receive the virtual image light beam and reflect the virtual image light beam to generate a scan beam to be irradiated on a screen. The screen may be coated with a photochromic material and configured to receive the scan beam from the scan mirror. Also, the screen may include a visible light transmittance characteristic that may be adjusted in response to the scan beam and effective to form the hologram of the object on the screen. The apparatus may be further adapted to utilize a plurality of reconstruction light sources and a shutter. Each of the reconstruction light sources may be configured to generate a reconstruction light beam corresponding to a wavelength in a different range. The shutter may be configured to receive the reconstruction light beams from the plurality of reconstruction light sources, and selectively pass one of the reconstruction light beams through the shutter to irradiate the screen to reconstruct the holographic image of the object.

In some examples, methods for generating a holographic image of an object are described. The example methods may include generating, by a plurality of light sources, a plurality of light beams corresponding to a different range of wavelengths. Switching operation may be performed, by a shutter, to selectively pass one of the plurality of light beams through the shutter. The light beam irradiated from the shutter may be split, by a beam splitter, into a first portion and a second portion of the light beam such that the first portion of the light beam is irradiated on the object. The second portion of the light beam may be received and reflected, by a mirror unit, to generate a reference beam. Some methods may further include detecting, by an image sensor array, an interference image caused by interference between the reference beam and the first portion of the light beam scattered by the object. The detected interference image may be converted, by a video signal generator unit, into an image signal.

In some examples, methods for reconstructing a holographic image of an object are described. The example methods may include receiving, by a receiver unit, an input signal representative of a hologram of the object. A virtual image light beam may be generated, by a virtual image light source, responsive to the input signal. The virtual image light beam may be received and reflected, by a scan mirror, to generate a scan beam. The scan beam from the scan mirror may be received, by a screen coated with a photochromic material, and the hologram of the object may be formed on the screen as a result of variations in the visible light transmittance characteristic of the screen in response to the scan beam. A reconstruction light beam corresponding to a wavelength in a different range may be generated by each of a plurality of reconstruction light sources. Some methods may further include receiving, by a shutter, the reconstruction light beams from the plurality of reconstruction light sources, and selectively passing one of the reconstruction light beams through the shutter to irradiate the screen to reconstruct the holographic image of the object.

In some examples, a computer-readable storage medium is described that may be adapted to store a program for causing a processor to generate a holographic image of an object. The processor may include various features as further described herein. The program may include one or more instructions for generating, by a plurality of light sources, a plurality of light beams corresponding to a different range of wavelengths, performing switching operation, by a shutter, to selectively pass one of the plurality of light beams through the shutter, and splitting, by a beam splitter, the light beam irradiated from the shutter into a first portion and a second portion of the light beam such that the first portion of the light beam is irradiated on an object. The program may further include one or more instructions for receiving and reflecting, by a mirror unit, the second portion of the light beam to generate a reference beam, detecting, by an image sensor array, an interference image caused by interference between the reference beam and the first portion of the light beam scattered by the object, and converting, by a video signal generator unit, the detected interference image into an image signal.

In some examples, a computer-readable storage medium is described that may be adapted to store a program for causing a processor to reconstruct a holographic image of an object. The processor may include various features as further described herein. The program may include one or more instructions for receiving, by a receiver unit, an input signal representative of a hologram of the object, generating, by a virtual image light source, a virtual image beam responsive to the input signal, and receiving and reflecting, by a scan mirror, the virtual image light beam to generate a scan beam. The program may further include receiving, by a screen coated with a photochromic material, the scan beam from the scan mirror, and forming the hologram of the object on the screen as a result of variations in the visible light transmittance characteristic of the screen in response to the scan beam. The program may further include generating, by each of a plurality of reconstruction light sources, a reconstruction light beam corresponding to a wavelength in a different range, and receiving, by a shutter, the reconstruction light beams from the plurality of reconstruction light sources, and selectively passing one of the reconstruction light beams through the shutter to irradiate the screen to reconstruct the holographic image of the object.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

The foregoing and other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

FIG. 1 schematically shows a block diagram of an illustrative example holographic image generator apparatus;

FIG. 2 schematically shows a perspective view of another illustrative example holographic image generator apparatus;

FIG. 3 schematically shows a block diagram of an illustrative example holographic imaging system including a holographic image generator apparatus coupled to a holographic image reconstruction apparatus through a network;

FIG. 4 schematically shows a block diagram of an illustrative example holographic image reconstruction apparatus;

FIG. 5 schematically shows a perspective view of another illustrative example holographic image reconstruction apparatus;

FIG. 6 schematically shows a perspective view of an illustrative example scan mirror that may be used in a holographic image reconstruction apparatus;

FIG. 7 illustrates an example flow diagram of a method adapted to generate a holographic image of an object;

FIG. 8 illustrates an example flow diagram of a method adapted to reconstruct a holographic image of an object;

FIG. 9 shows a schematic block diagram illustrating an example computing system that can be configured to perform methods for generating and/or reconstructing a holographic image of an object;

FIG. 10 illustrates computer program products that can be utilized to generate a holographic image of an object; and

FIG. 11 illustrates computer program products that can be utilized to reconstruct a holographic image of an object, all arranged in accordance with at least some embodiments described herein.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

This disclosure is generally drawn, inter alia, to methods, apparatus, systems, devices and computer program products related to generating and reconstructing color holographic images.

Briefly stated, technologies are generally related to holographic imaging. In some examples, techniques are described for generating a holographic image of an object using a plurality of light sources, a shutter, and an image sensor array. Each of the light sources is configured to generate a light beam using a respective wavelength in a different range. In various examples, an apparatus as described here may be configured to control the shutter to receive the light beams from the plurality of light sources and selectively pass each of the received light beams to provide a selected light beam. The apparatus may further include a beam splitter and a mirror unit configured to generate an object light beam and a reference light beam from the selected light beam. The apparatus may include an image sensor array configured to detect an image of interference caused by the reference light beam and the object light beam.

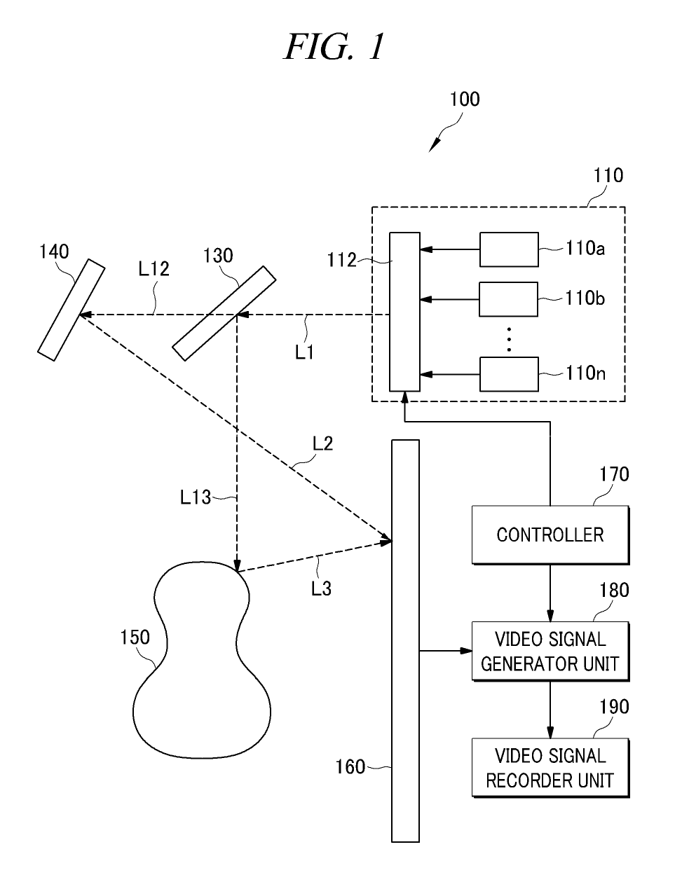

FIG. 1 schematically shows a block diagram of an illustrative example holographic image generator apparatus, arranged in accordance with at least some embodiments described herein. As depicted, a holographic image generator apparatus 100 may include a light source unit 110 with a plurality of light sources 110a to 110n, each being configured to generate a coherent light beam, such as a visible laser light beam. The coherent light beams of each light source may correspond to a different range of wavelengths, either overlapping in ranges or non-overlapping in ranges. An example light source unit 110 may include a red laser light source, a green laser light source and a blue laser light source, although many other wavelengths and types of light sources are contemplated.

In some embodiments, light source unit 110 of holographic image generator apparatus 100 may further include a shutter 112 configured to receive the light beams from the plurality of light sources 110a to 110n and selectively pass each of the received light beams to provide a selected light beam L1. In case where light source unit 110 includes three color light sources, e.g., a red laser light source, a green laser light source, and a blue laser light source, shutter 112 may be configured to selectively pass (e.g., sequentially and/or repeatedly actuating shutter 112) one of a red laser light, a green laser light and a blue laser light. Light beam L1 provided by shutter 112 may be transmitted to a beam splitter 130.

In some embodiments, beam splitter 130 may be configured to collaboratively operate with light source unit 110 and a mirror unit 140. Beam splitter 130 may be implemented using any suitable materials including an aluminum layer formed on a glass substrate. For example, beam splitter 130 may be configured to split the selected light beam L1 into a first light beam L13 and a second light beam L12. Beam splitter 130 may also be configured to irradiate an object 150 with first light beam L13 such that at least part of first light beam L13 may be scattered by object 150 to generate an object light beam L3. Beam splitter 130 may also be configured to irradiate mirror unit 140 with second light beam L12. Mirror unit 140 may be configured to reflect at least part of second light beam L12 to generate a reference light beam L2, such that object light beam L3 and reference light beam L2 may cause interference patterns to be formed on an image sensor array 160.

When two light beams, such as light beams L2 and L3, reach the surface of image sensor array 160, the light waves may intersect and interfere with each other. The interference pattern formed by the intersecting light waves may represent the manner in which the scene's light from object 150 interferes with the original light source from the light source unit 110. Image sensors in image sensor array 160 may be configured to detect and receive images of the interference patterns.

In some embodiments, holographic image generator apparatus 100 may further include a video signal generator unit 180 configured to convert the image detected by image sensor array 160 into an image signal associated with each of the plurality of light sources 110a to 110n.

In some embodiments, image sensor array 160 may include a charge coupled device (CCD) array or any other types of imaging sensors. Also, image sensor array 160 may include a sensor array configured in a two dimensional plane or any other shapes. For example, image sensor array may include an array of sensors configured in a shape of a cylinder or a polygonal prism that substantially surrounds object 150.

In some embodiments, holographic image generator apparatus 100 may further include a controller 170 configured to selectively control operation of shutter 112 and video signal generator unit 180. Controller 170 may be configured to store a control program that may be used by controller 170 in operation of holographic image generator apparatus 100. Additionally, holographic image generator apparatus 100 may include a video signal recorder unit 190 configured to capture (or record) the image signal from video signal generator unit 180 in a storage unit (not shown).

In case where light source unit 110 includes three color light sources, e.g., a red laser light source, a green laser light source, and a blue laser light source, controller 170 may be configured to control operation of holographic image generator apparatus 100 as follows. Shutter 112 may be configured to selectively pass (e.g., via switching operations) a red laser light L1 from the red laser light source. The red laser light L1 may be split into two light beams L12 and L13 by beam splitter 130, where one split light beam L13 may be irradiated on object 150 and may be scattered from object 150 to generate object light beam L3, which may be made incident on image sensor array 160. The other split light beam L12 may be reflected by mirror unit 140 to generate reference light beam L2, which may also be incident on image sensor array 160. Then, at least a portion of a hologram of object 150 can be generated by interference between object light beam L3 and reference light beam L2 (hereinafter referred to as a red hologram) may be formed on image sensor array 160. Further, video signal generator unit 180 may generate at least a portion of a holographic video signal based on the red hologram formed on image sensor array 160 (hereinafter referred to as a red holographic video signal). Video signal recorder unit 190 may record the red holographic video signal.

Further, shutter 112 may be selectively pass (e.g. via actuation or switched operation) a green laser light from the green laser light source. A green hologram of object 150 may be formed on image sensor array 160 in the same manner as described above. Then, video signal generator unit 180 may generate a green holographic video signal based on the green hologram formed on image sensor array 160. Video signal recorder unit 190 may record (or capture) the green holographic video signal. Similarly, shutter 112 may be selectively pass (e.g., via actuation or switched operation) a blue laser light from the blue laser light source, and a blue holographic video signal may be generated by video signal generator unit 180 based on a blue hologram formed on image sensor array 160. Video signal recorder unit 190 may be configured to record the blue holographic video signal.

In some embodiments, the above-described operations for generating each of the three-color holographic video signals may be executed in a range from about 1 to 5 milliseconds. Further, these operations may be repeatedly performed until holographic image generation apparatus 100 is turned off. In the above embodiments, since shutter 112 can be controlled to selectively pass one of the plurality of light sources 110a to 110n at a high speed, holographic image generation apparatus 100 can be effectively utilized to generate a color stereoscopic holographic image, e.g., in a field sequential color system.

In FIG. 1, one light source unit 110 and corresponding beam splitter 130 and mirror unit 140 are illustrated for the sake of explanation. However, the number of light sources, beam splitters and mirror units may not be limited thereto. In some examples, two or more pairs of light sources and beam splitters (and mirror units) may be arranged depending on the desired implementation. In one example, light beam L1 from the light source unit 110 may be reflected by at least one additional mirror (not shown), effective to irradiate the beam splitter 130 through an indirect path. In another example, light beam L13 from beam splitter 130 can be reflected by at least one additional mirror (not shown) to irradiate object 150 with light beam L13 from an indirect path. In still another example, mirror 140 may be eliminated and light beam L12 can be directly incident on image sensor array 160. In still further examples, light beam L3 can be indirectly received from the image sensor array 160 from at least one additional mirror (not shown). Additional examples of direct and indirect light paths using optical devices such as beam splitters, mirrors, lenses, and the like are contemplated and considered within the scope of the present disclosure.

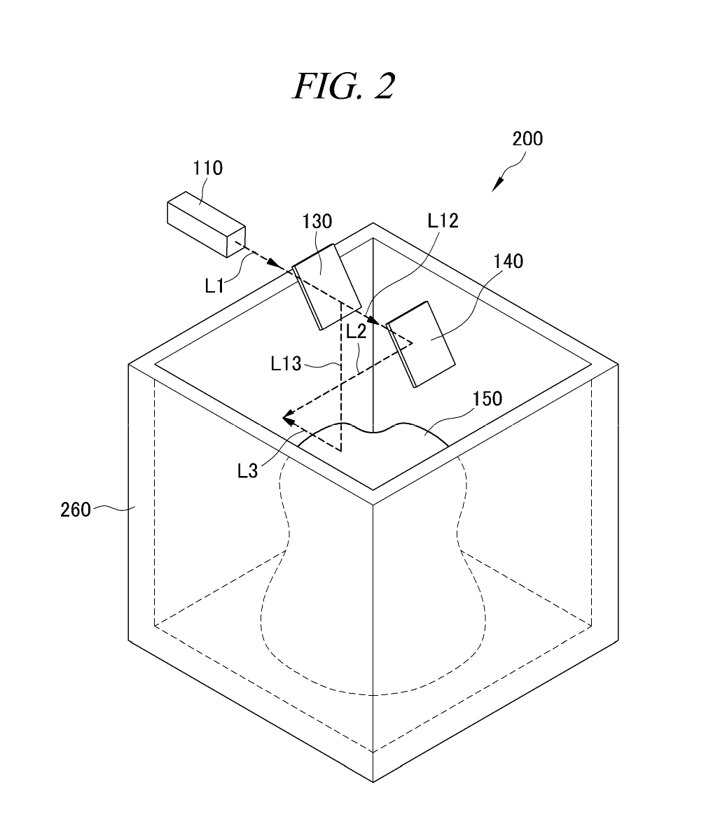

FIG. 2 schematically shows a perspective view of another illustrative example holographic image generator apparatus, arranged in accordance with at least some embodiments described herein. A holographic image generator apparatus 200 has a similar configuration to holographic image generator apparatus 100 as shown in FIG. 1, except for that an image sensor array 260 is arranged in a shape of a rectangular prism. As depicted, image sensor array 260 may have a rectangular prism-shaped inner surface where an array of imaging sensors (e.g., CCD sensor devices) may be arranged. In an alternative embodiment, image sensor array 260 may have any other suitable shape of the inner surface, such as a cylindroid or other polygonal prism.

Similar to holographic image generator apparatus 100 shown in FIG. 1, apparatus 200 may include a light source unit 110 including a plurality of light sources, each being configured to generate a coherent light beam, such as a visible laser light beam, each corresponding to a wavelength in a different range, either overlapping or non-overlapping in ranges with the wavelength of the other light sources. In some embodiments, light source unit 110 may include a red laser light source, a green laser light source and a blue laser light source.

In some embodiments, holographic image generator apparatus 200 may further include a shutter in light source unit 110 configured to receive the light beams from the plurality of light sources and selectively pass each of the received light beams in turn to provide a selected light beam L1. The light beam L1 provided by the shutter in the light source unit 110 may be transmitted to a beam splitter 130.

In some embodiments, beam splitter 130 may be configured to collaboratively operate with light source unit 110 and a mirror unit 140. Beam splitter 130 may be implemented using any suitable materials including an aluminum layer formed on a glass substrate. For example, beam splitter 130 may be configured to split light beam L1 into a first light beam L13 and a second light beam L12. Beam splitter 130 may also be configured to irradiate an object 150 with first light beam L13 such that at least part of first light beam L13 may be scattered by object 150 to generate an object light beam L3. Beam splitter 130 may also be configured to irradiate mirror unit 140 with second light beam L12. Mirror unit 140 may be configured to reflect at least part of second light beam L12 to generate a reference light beam L2, such that object light beam L3 and reference light beam L2 may cause interference patterns to be formed on image sensor array 260.

In some embodiments, holographic image generator apparatus 200 may further include a video signal generator unit (not shown) configured to convert the image detected by image sensor array 260 into an image signal associated with each of the plurality of light sources in light source unit 110. Additionally, holographic image generator apparatus 200 may include a video signal recorder unit (not shown) configured to record the image signal from video signal generator unit in a storage unit.

In some embodiments, operations for generating multiple color holographic video signals (e.g., red, green and blue holographic video signals) may be executed by holographic image generator apparatus 200 in a similar manner as described above with reference to FIG. 1. Such operations for generating each of the color holographic video signals may be performed in a range from about 1 to 5 milliseconds and may be repeatedly performed until holographic image generation apparatus 200 is turned off. In the above embodiments, since the shutter can be controlled to selectively pass one of the plurality of light sources at a high speed, holographic image generation apparatus 200 can be effectively utilized to generate a color stereoscopic holographic image, e.g., in a field sequential color system.

In FIG. 2, one light source unit 110 and corresponding beam splitter 130 and mirror unit 140 are illustrated for the sake of explanation. However, the number of light sources, beam splitters and mirror units may not be limited thereto. In some examples, four pairs of light sources and beam splitters (and mirror units) may be arranged in correspondence with four inner surfaces in rectangular prism shaped image sensor array 260.

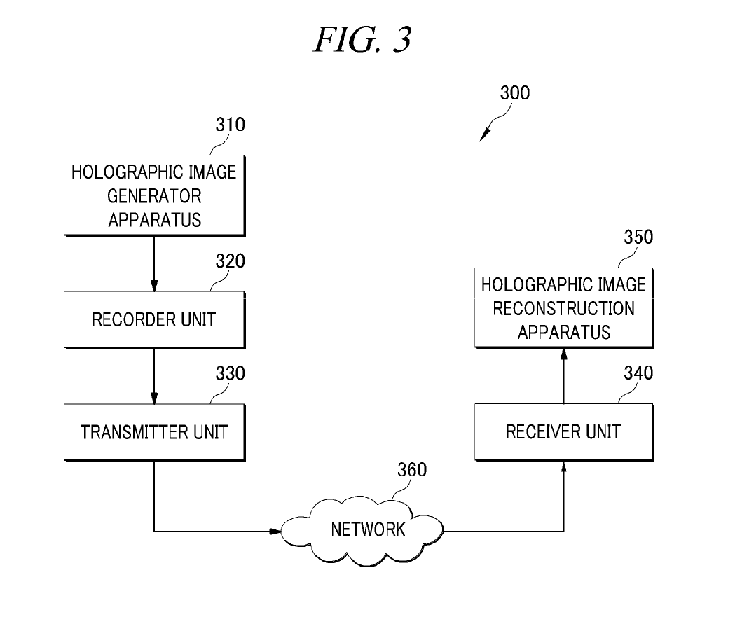

In some embodiments, the image signals generated by holographic image generator apparatus 100 or 200 according to the above embodiments may be recorded in a local storage unit and/or transmitted to a holographic image reconstruction apparatus. FIG. 3 schematically shows a block diagram of an illustrative example holographic imaging system including a holographic image generator apparatus coupled to a holographic image reconstruction apparatus through a network, in accordance with at least some embodiments described herein. As depicted, a holographic imaging system 300 may include a holographic image generator apparatus 310, which may be coupled to a recorder unit 320 and a transmitter unit 330. Transmitter unit 330 may be coupled to receiver unit 340 through one or more networks 360. Receiver unit 340 may be coupled to a holographic image reconstruction apparatus 350.

In some embodiments, holographic image generator apparatus 310 may have a similar configuration to holographic image generator apparatus 100 or 200 as shown in FIGS. 1 and 2. Holographic image generator apparatus 310 may be configured to generate image signals in a similar manner as described above with reference to FIGS. 1 and 2. Thus generated digital image signals may be transmitted and recorded in recorder unit 320. The image signals recorded in recorder unit 320 may be read by transmitter unit 330 and sent to a remote device, such as a receiver unit 340 or a holographic image reconstruction apparatus 350, through a network 360.

Receiver unit 340 may be configured to receive the image signals from transmitter unit 330 and transmit the image signals to holographic image reconstruction apparatus 350.

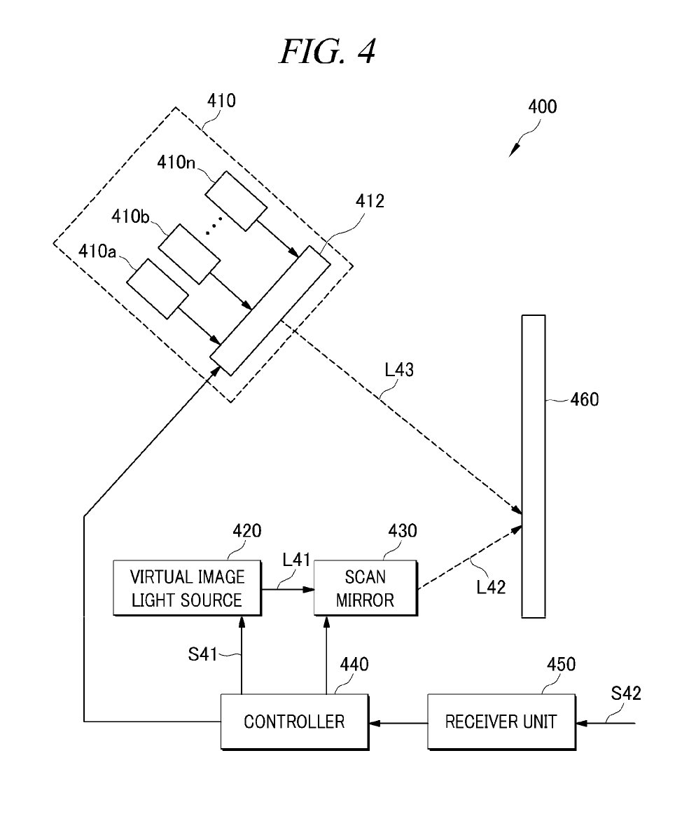

In some embodiments, holographic image reconstruction apparatus 350 may be configured to reconstruct images of object 150 based on the received image signals. FIG. 4 schematically shows a block diagram of an illustrative example holographic image reconstruction apparatus, arranged in accordance with at least some embodiments described herein.

As shown in FIG. 4, a holographic image reconstruction apparatus 400 may include a virtual image light source 420 configured to generate a virtual image light beam L41, such as an ultraviolet laser beam or an electron beam, based on a holographic image signal S41. In some embodiments, the holographic image signal S41 may be provided from a receiver unit 450 or a holographic image generator apparatus such as holographic image generator apparatus 100, 200 or 310 in FIGS. 1 to 3. Thus generated virtual image light beam L41 may have intensities which may vary based on the levels of the holographic image signal S41. Virtual image light source 420 may be configured to irradiate the generated virtual image light beam L41 onto a scan mirror 430. Scan mirror 430 may be configured to reflect the virtual image light beam and generate a scan beam L42 that is irradiated on a screen 460.

In some embodiments, screen 460 may be coated with a photochromic material and configured to form a hologram of an object, such as object 150, using a visible light transmittance characteristic that is adjusted in response to the scan beam L42 from scan mirror 430. For example, screen 460 may include a photochromic material formed on a transparent layer. The transparent layer may be formed of at least one of a quartz glass material, a borosilicate glass material, a transparent plastic material and PET (polyethylene terephthalate). The photochromic material may include at least one of KTaO₃ doped with an impurity and SrTiO₃ doped with an impurity. The impurity doped into the photochromic material may include nickel (Ni) and/or iron (Fe). Additionally or alternatively, the photochromic material may include an organic photochromic material such as HABI (hexaarylbiimidazole).

In some embodiments, when screen 460 coated with a photochromic material such as KTaO₃ doped with Ni and Fe is irradiated with the scan beam L42, electrons in the photochromic material may be excited by the scan beam L42 and trapped in complex defects formed by the impurity Ni and oxygen vacancies. Specifically, one or two electrons may be trapped by a complex defect of an Ni ion with an oxygen vacancy VO at the center (Ni³⁺—VO), whereby the complex defect (Ni³⁺—VO) becomes (Ni³⁺—VO-2e) or (Ni³⁺—VO-e). Complex defects having trapped electrons may exhibit sufficiently wide absorption characteristics for light with visible spectrum. In particular, (Ni³⁺—VO-2e) has a light absorption peak at the wavelength of 630 nm and has a wide absorption band. On the other hand, an iron ion (Fe³⁺) traps holes to beam Fe⁴⁺, and the center of the impurity has an absorption band having a peak at about 440 nm. Thus, KTaO₃ doped with both Ni and Fe, when irradiated with the scan beam L42 such as ultraviolet light beam or electron beam, exhibits a wide absorption band over the entire visible spectrum including red, green and blue color spectrum.

On screen 460 coated with the photochromic material having the above-described characteristics, holograms may be formed by changing a visible light transmittance of the photochromic material in response to the varying intensities of the virtual image light beams such as scan beams L42. That is, images of an object corresponding to the holographic image signals may be formed on screen 460 in the form of images representing varying visible light transmittance.

In some embodiments, holographic image reconstruction apparatus 400 may further include a reconstruction light source unit 410, which may include a plurality of reconstruction light sources 410a to 410n. Each of reconstruction light sources 410a to 410n may be configured to irradiate a reconstruction light beam corresponding to a wavelength in a different range, such as a visible laser beam, towards screen 460. For example, the plurality of reconstruction light sources 410a to 410n may include a red laser light source, a green laser light source, and a blue laser light source.

In some embodiments, reconstruction light source unit 410 of holographic image generator apparatus 400 may further include a shutter 412 configured to receive the reconstruction light beams from the plurality of reconstruction light sources 410a to 410n and selectively pass (e.g., via actuated or switched operation) each of the received light beams in turn to provide a selected light beam L43. In case where reconstruction light source unit 410 includes three color light sources, e.g., a red laser light source, a green laser light source, and a blue laser light source, shutter 412 may be sequentially switched to pass one of a red laser light, a green laser light and a blue laser light. Light beam L43 provided by shutter 412 may be transmitted to screen 460. When the holograms formed on screen 460 are irradiated with reconstruction light beam L43, an image of the object may be reconstructed.

In some embodiments, holographic image reconstruction apparatus 400 may further include a controller 440 configured to control operation of one or more of shutter 412, virtual image light source 420 and/or scan mirror 430. Controller 440 may be configured to store a control program that may be used by controller 170 in operation of holographic image reconstruction apparatus 400. Additionally, holographic image reconstruction apparatus 400 may include receiver unit 450 configured to receive an input signal S42 representative of a hologram of the object from an external device such as holographic image generator apparatus 100, 200 or 310.

In case where light source unit 410 includes three color light sources, e.g., a red laser light source, a green laser light source, and a blue laser light source, controller 440 may be configured to control operation of holographic image reconstruction apparatus 400 as follows. Shutter 412 may be configured to selectively pass (e.g., via switching operations) a red laser light L43 from the red laser light source. The red laser light L43 may be made incident on the holograms formed on screen 460, and thus, a red-color image of the object may be reconstructed. Further, shutter 412 may be configured to selectively pass a green laser light L43 from the green laser light source. A green-color image of the object may be reconstructed on screen 460 in the same manner as described above. Similarly, shutter 412 may be configured to selectively pass a blue laser light L43 from the blue laser light source, and a blue-color image of the object may be reconstructed on screen 460.

In some embodiments, the above-described operations for reconstructing each of three color holographic images may be executed in a range from about 1 to 5 milliseconds. Further, these operations may be repeatedly performed until holographic image reconstruction apparatus 400 is turned off. In the above embodiments, since shutter 412 can be controlled to selectively pass one of the plurality of reconstruction light sources 410a to 410n at a high speed, holographic image reconstruction apparatus 400 can be effectively utilized to reconstruct a color stereoscopic holographic image, e.g., in a field sequential color system.

In FIG. 4, one virtual image light source 420 and corresponding scan mirror 430 are illustrated for the sake of explanation. However, the number of virtual image light sources and scan mirrors may not be limited thereto. In some examples, two or more pairs of virtual image light sources and scan mirrors may be arranged depending on the desired implementation.

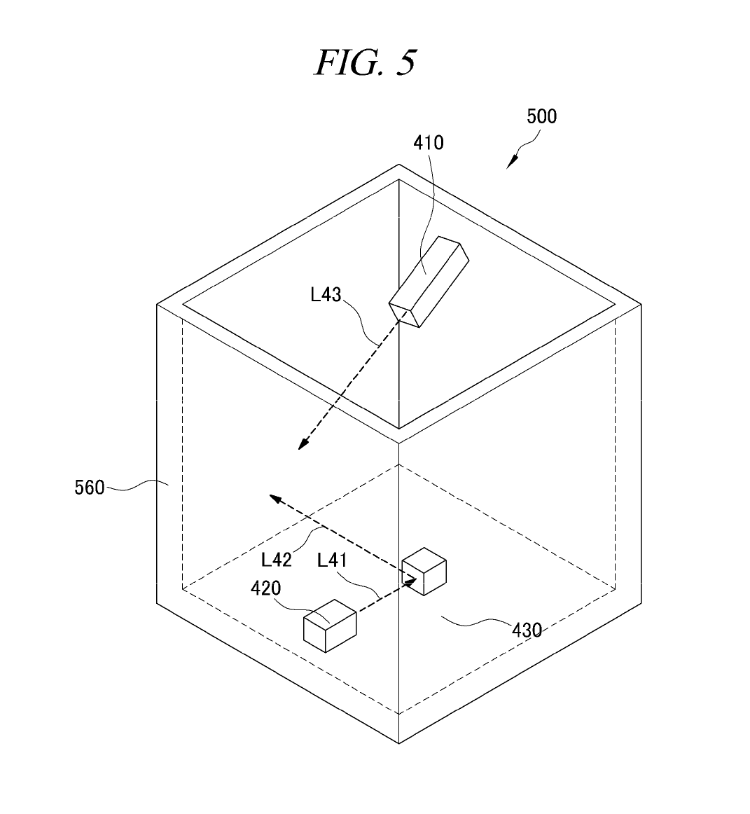

FIG. 5 schematically shows a perspective view of another illustrative example holographic image reconstruction apparatus, arranged in accordance with at least some embodiments described herein. A holographic image reconstruction apparatus 500 has a similar configuration to holographic image reconstruction apparatus 400 as shown in FIG. 4 except for that a screen 560 is arranged in a shape of a rectangular prism. As depicted, screen 560 may have a rectangular prism-shaped inner surface that may be coated with a photochromic material. In an alternative embodiment, screen 560 may have any other suitable shape of the inner surface, such as a cylindroid or other polygonal prism.

In some embodiments, screen 560 may be configured to form a hologram of an object, such as object 150, using a visible light transmittance characteristic that can be adjusted in response to the scan beam L42 from scan mirror 430. For example, screen 560 may include a photochromic material formed on a transparent layer. The transparent layer may be formed of at least one of a quartz glass material, a borosilicate glass material, a transparent plastic material and PET (polyethylene terephthalate). The photochromic material may include at least one of KTaO₃ doped with an impurity and SrTiO₃ doped with an impurity. The impurity doped into the photochromic material may include nickel (Ni) and/or iron (Fe). Additionally or alternatively, the photochromic material may include an organic photochromic material such as HABI (hexaarylbiimidazole).

Similar to holographic image reconstruction apparatus 400 shown in FIG. 4, apparatus 500 may include a virtual image light source 420 configured to generate a virtual image light beam L41, such as an ultraviolet laser beam or an electron beam, based on a holographic image signal. In some embodiments, the holographic image signal may be provided from a holographic image generator apparatus such as holographic image generator apparatus 100, 200 or 310 in FIGS. 1 to 3. Thus generated virtual image light beam L41 may have intensities which may vary based on the level of the holographic image signal, e.g., based on a value of a color component represented by the holographic image signal. Virtual image light source 420 may be configured to irradiate the generated virtual image light beam L41 onto a scan mirror 430. Scan mirror 430 may be configured to reflect the virtual image light beam and generate a scan beam L42 that is irradiated on screen 560.

In some embodiments, holographic image reconstruction apparatus 500 may further include a reconstruction light source unit 410, which may include a plurality of reconstruction light sources (not shown) such as reconstruction light sources 410a to 410n. Each of the reconstruction light sources may be configured to irradiate a reconstruction light beam corresponding to a wavelength in a different range, such as a visible laser beam, on screen 560. For example, the plurality of reconstruction light sources may include a red laser light source, a green laser light source, and a blue laser light source.

In some embodiments, reconstruction light source unit 410 of holographic image generator apparatus 500 may further include a shutter (not shown), such as shutter 412, configured to receive the reconstruction light beams from the plurality of reconstruction light sources and selectively pass each of the received light beams to provide a selected light beam L43. When the hologram formed on screen 560 is irradiated with the reconstruction light beam L43, an image of the object may be reconstructed.

In some embodiments, holographic image reconstruction apparatus 500 may further include a controller (not shown) configured to control operation of one or more of the shutter, virtual image light source 420 and/or scan mirror 430. Controller 440 may be configured to store a control program to control operation of holographic image reconstruction apparatus 500. Additionally, holographic image reconstruction apparatus 500 may include a receiver unit (not shown) configured to receive an input signal representative of a hologram of the object from an external device such as holographic image generator apparatus 100, 200 or 310.

In some embodiments, operations for reconstructing multiple color holographic images (e.g., red, green and blue holographic images) may be executed by holographic image generator apparatus 500 in a similar manner as described above with reference to FIG. 4. Such operations for reconstructing each of the color holographic images may be performed in a range from about 1 to 5 milliseconds and may be repeatedly performed until holographic image reconstruction apparatus 500 is turned off or otherwise disabled in operation. In the above embodiments, since the shutter can be controlled to selectively pass one of the plurality of reconstruction light sources at a high speed, holographic image generation apparatus 500 can be effectively utilized to reconstruct a color stereoscopic holographic image, e.g., in a field sequential color system.

In FIG. 5, one virtual image light source 420 and corresponding scan mirror 430 are illustrated for the sake of explanation. However, the number of virtual image light sources and scan mirrors may not be limited thereto. In some examples, four pairs of virtual image light sources and scan mirrors may be arranged in correspondence with four inner surfaces in rectangular prism shaped screen 560.

As illustrated in FIG. 5, screen 560 may be arranged in a shape of a polygonal prism such as a rectangular prism. Alternatively, screen 560 may be arranged in a shape of a cylinder or any other shapes such as a cylindroid. Also, scan mirror 420 may be actuated by any variety of mechanisms such as magnetic actuation, electrical actuation, or electromagnetic actuation, wherein the actuation of the scan mirror 420 is effective to steer the scan beam (e.g., actuation may facilitate a change the direction of virtual image light beams reflected on surfaces of scan mirror 420).

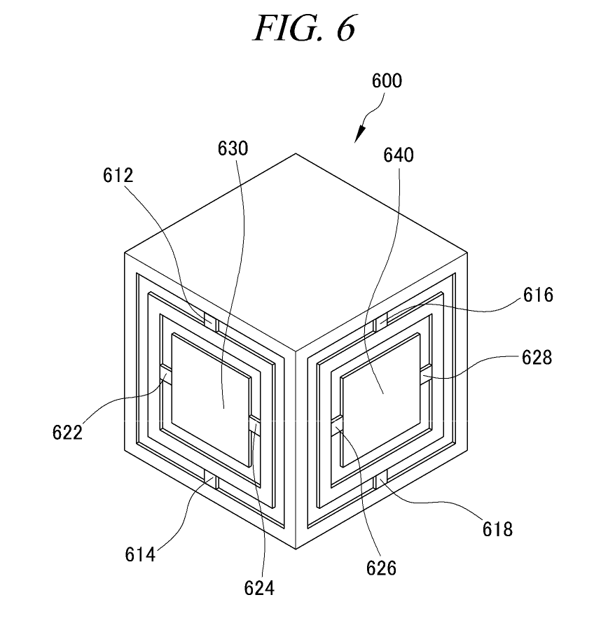

FIG. 6 schematically shows a perspective view of an illustrative example scan mirror that may be used in a holographic image reconstruction apparatus, in accordance with at least some embodiments described herein. As depicted, a scan mirror 600 may include vertical axis 612, 614, 616 and 618, along which mirror portions 630 and 640 may be actuated to rotate in a horizontal direction. Further, scan mirror 600 may include horizontal axis 622, 624, 626 and 628, along which mirror portions 630 and 640 may be actuated to rotate in a vertical direction.

In some embodiments, the rotational actuation of mirror portions 630 and 640 may be driven by electric, magnetic, or electromagnetic forces, which may be again generated based on electric control signals provided from a holographic image reconstruction apparatus such as holographic image reconstruction apparatus 500 in FIG. 5. In some examples, scan mirror 600 may be implemented using MEMS (micro-electro-mechanical systems) technologies, in which mirror portions 630 and 640 may be actuated by piezoelectric force, which may be again generated based on electric control signals provided from the holographic image reconstruction apparatus.

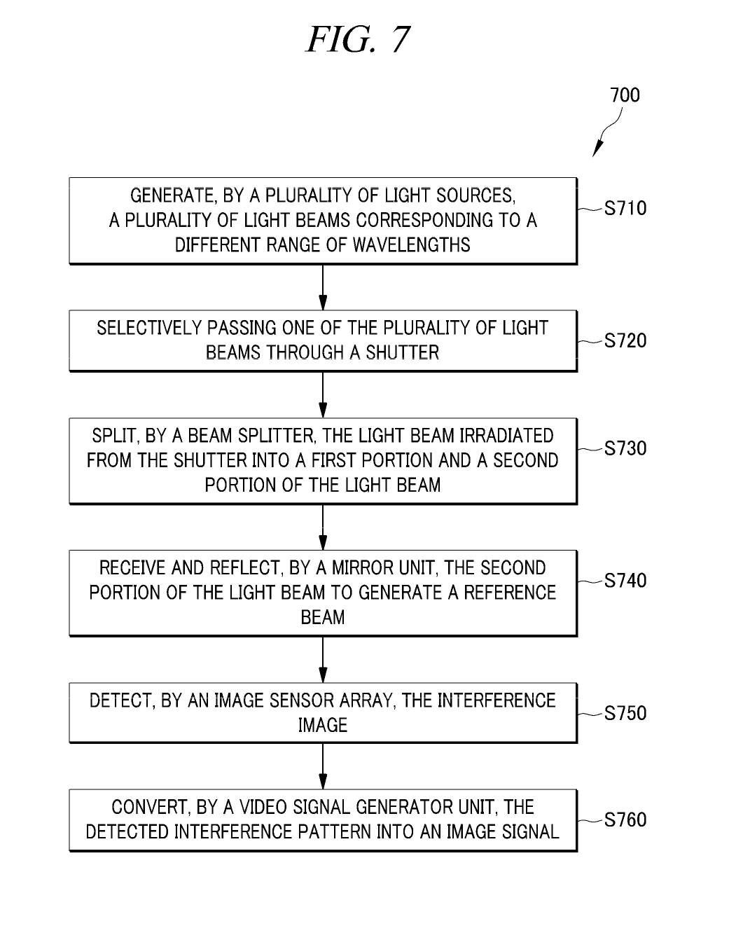

FIG. 7 illustrates an example flow diagram of a method adapted to generate a holographic image of an object, arranged in accordance with at least some embodiments described herein. An example method 700 in FIG. 7 may be implemented using, for example, a computing device including a processor adapted to generate holographic images.

Method 700 may include one or more operations, actions, or functions as illustrated by one or more of blocks S710, S720, S730, S740, S750 and/or S760. Although illustrated as discrete blocks, various blocks may be divided into additional blocks, combined into fewer blocks, or eliminated, depending on the desired implementation. In some further examples, the various described blocks may be implemented as a parallel process instead of a sequential process, or as a combination thereof. Method 700 may begin at block S710, “GENERATE, BY A PLURALITY OF LIGHT SOURCES, A PLURALITY OF LIGHT BEAMS CORRESPONDING TO A DIFFERENT RANGE OF WAVELENGTHS.”

At block S710, a plurality of light beams may be generated by a plurality of light sources, where each of the plurality of light sources is operable to generate light corresponding to a wavelength in a different range. As depicted in FIGS. 1 and 2, each of a plurality of light sources 110a to 110n may be configured to generate a coherent light beam, such as a visible laser light beam, corresponding to a wavelength in a different range. In some embodiments, light sources 110a to 110n may include a red laser light source, a green laser light source and a blue laser light source. Block S710 may be followed by block S720, “SELECTIVELY PASSING ONE OF THE PLURALITY OF LIGHT BEAMS THROUGH A SHUTTER.”

At block S720, a switching operation may be performed by a shutter (e.g., dynamic actuation of the shutter) to selectively pass one of the plurality of light beams through the shutter. As illustrated in FIGS. 1 and 2, a shutter 112 may receive the light beams from the plurality of light sources 110a to 110n and selectively pass each of the received light beams to provide a selected light beam L1. In cases where the plurality of light sources 110a to 110n includes three color light sources, e.g., a red laser light source, a green laser light source, and a blue laser light source, shutter 112 may selectively pass one of a red laser light, a green laser light and a blue laser light. Block S720 may be followed by block S730, “SPLIT, BY A BEAM SPLITTER, THE LIGHT BEAM IRRADIATED FROM THE SHUTTER INTO A FIRST PORTION AND A SECOND PORTION OF THE LIGHT BEAM.”

At block S730, the light beam irradiated from the shutter may be split, by a beam splitter, into a first portion and a second portion of the light beam. The first portion of the light beam is then transmitted towards the object. As illustrated in FIGS. 1 and 2, a beam splitter 130 may be configured to split the selected light beam L1 into a first light beam L13 and a second light beam L12. The first light beam L13 may be irradiated on an object 150 such that at least part of the first light beam L13 may be scattered by object 150 to generate an object light beam L3. Block S730 may be followed by block S740, “RECEIVE AND REFLECT, BY A MIRROR UNIT, THE SECOND PORTION OF THE LIGHT BEAM TO GENERATE A REFERENCE BEAM.”

At block S740, the second portion of the light beam may be received and reflected, by a mirror unit, to generate a reference beam. As depicted in FIGS. 1 and 2, a mirror unit 140 may be configured to reflect at least part of second light beam L12 to generate a reference light beam L2, such that object light beam L3 and reference light beam L2 may cause interference patterns to be formed on an image sensor array 160. Block S740 may be followed by block S750, “DETECT, BY AN IMAGE SENSOR ARRAY, THE INTERFERENCE IMAGE.”

At block S750, an interference image caused by interference between the reference beam and the first portion of the light beam scattered by the object may be detected by an image sensor array. For example, as shown in FIGS. 1 and 2, when two light beams L2 and L3 reach the surface of image sensor array 160, the light waves may intersect and interfere with each other effective to form an interference pattern. The interference pattern formed by the intersecting light waves may represent the manner in which the scene's light from object 150 interferes with the original light source. Image sensors (e.g., from an image sensor array 160) may be configured to detect and receive images of the interference patterns. Block S750 may be followed by block S760, “CONVERT, BY A VIDEO SIGNAL GENERATOR UNIT, THE DETECTED INTERFERENCE PATTERN INTO AN IMAGE SIGNAL.”

At block S760, the detected interference pattern may be converted, by a video signal generator unit, into an image signal. As depicted in FIGS. 1 and 2, a video signal generator unit 180 may convert the image detected by image sensor array 160 into an image signal associated with each of the plurality of light sources 110a to 110n.

In some embodiments, method 700 may be repeatedly performed for each light beam selectively generated from the plurality of light sources. For example, in case where the plurality of light sources 110a to 110n includes three color light sources, e.g., a red laser light source, a green laser light source, and a blue laser light source, method 700 may be repeatedly performed to sequentially generate red, green and blue holographic image signals. Also, method 700 including the above-described operations for generating each of the three-color holographic video signals may be executed in a range from about 1 to 5 milliseconds.

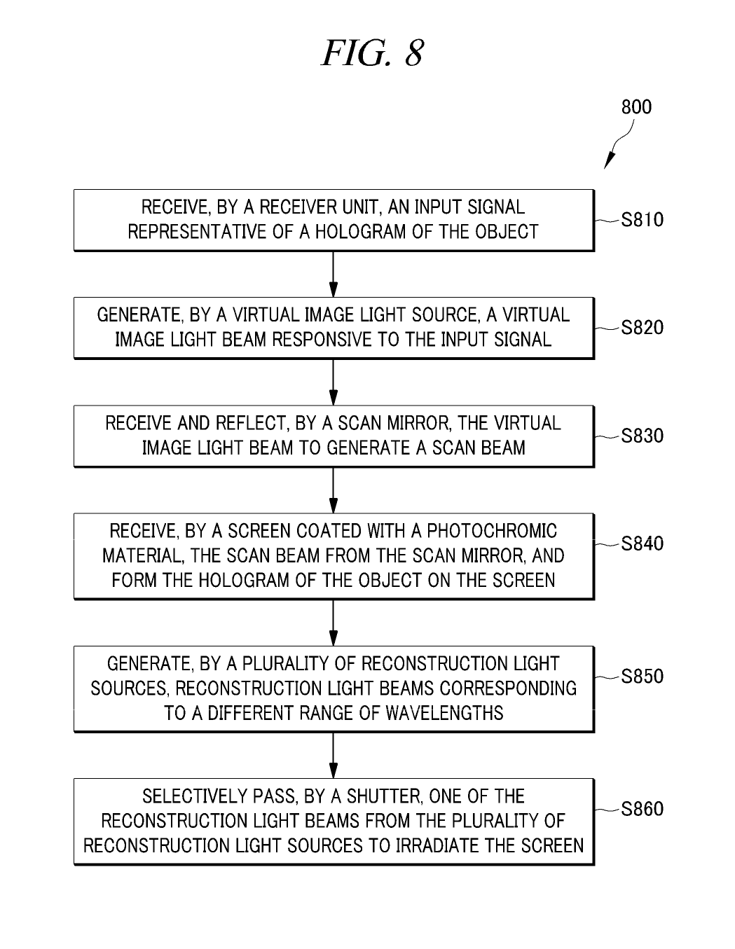

FIG. 8 illustrates an example flow diagram of a method adapted to reconstruct a holographic image of an object, arranged in accordance with at least some embodiments described herein. An example method 800 in FIG. 8 may be implemented using, for example, a computing device including a processor adapted to reconstruct holographic images.

Method 800 may include one or more operations, actions, or functions as illustrated by one or more of blocks S810, S820, S830, S840, S850 and/or S860. Although illustrated as discrete blocks, various blocks may be divided into additional blocks, combined into fewer blocks, or eliminated, depending on the desired implementation. In some further examples, the various described blocks may be implemented as a parallel process instead of a sequential process, or as a combination thereof. Method 800 may begin at block S810, “RECEIVE, BY A RECEIVER UNIT, AN INPUT SIGNAL REPRESENTATIVE OF A HOLOGRAM OF THE OBJECT.”

At block S810, an input signal representative of a hologram of the object may be received by a receiver unit. For example, as depicted in FIGS. 4 and 5, receiver unit 450 may receive an input signal representative of a hologram of the object or at least portion of the hologram, e.g., from a holographic image generator apparatus through one or more networks. Block S810 may be followed by block S820, “GENERATE, BY A VIRTUAL IMAGE LIGHT SOURCE, A VIRTUAL IMAGE LIGHT BEAM RESPONSIVE TO THE INPUT SIGNAL.”

At block S820, a virtual image light beam responsive to the input signal may be generated by a virtual image light source. As illustrated in FIGS. 4 and 5, a virtual image light source 420 may be configured to generate a virtual image light beam L41, such as an ultraviolet laser beam or an electron beam, based on holographic image signals. In some embodiments, the holographic image signals may be provided from a holographic image generator apparatus such as holographic image generator apparatus 100, 200 or 310 in FIGS. 1 to 3. Thus generated virtual image light beams L41 may have intensities which may vary based on the levels of the holographic image signals. Virtual image light source 420 may be configured to irradiate the generated virtual image light beams L41 onto a scan mirror 430. Block S820 may be followed by block S830, “RECEIVE AND REFLECT, BY A SCAN MIRROR, THE VIRTUAL IMAGE LIGHT BEAM TO GENERATE A SCAN BEAM.”

At block S830, the virtual image light beam may be received and reflected, by a scan mirror, to generate a scan beam. As depicted in FIGS. 4 and 5, scan mirror 430 may be configured to receive and reflect the virtual image light beams and generate a scan beam L42 that is irradiated on a screen 460. Block S830 may be followed by block S840, “RECEIVE, BY A SCREEN COATED WITH A PHOTOCHROMIC MATERIAL, THE SCAN BEAM FROM THE SCAN MIRROR, AND FORM THE HOLOGRAM OF THE OBJECT ON THE SCREEN.”

At block S840, the scan beam from the scan mirror may be received, by a screen coated with a photochromic material, and the hologram of the object on the screen may be formed as a result of variations in the visible light transmittance characteristic of the screen in response to the scan beam. For example, as shown in FIGS. 4 and 5, on screen 460 coated with a photochromic material, holograms may be formed by changing a visible light transmittance of the photochromic material in response to the varying intensities of the virtual image light beams such as scan beams L42. That is, images of an object corresponding to the holographic image signals may be formed on screen 460 in the form of images representing varying visible light transmittance. Block S840 may be followed by block S850, “GENERATE, BY A PLURALITY OF RECONSTRUCTION LIGHT SOURCES, RECONSTRUCTION LIGHT BEAMS CORRESPONDING TO A DIFFERENT RANGE OF WAVELENGTHS.”

At block S850, reconstruction light beams corresponding to a different range of wavelengths may be generated by a plurality of reconstruction light sources. As shown in FIGS. 4 and 5, each of reconstruction light sources 410a to 410n may be configured to irradiate a reconstruction light beam corresponding to a wavelength in a different range, such as a visible laser beam, on screen 460. For example, the plurality of reconstruction light sources 410a to 410n may include a red laser light source, a green laser light source, and a blue laser light source. Block S850 may be followed by block S860, “SELECTIVELY PASS, BY A SHUTTER, ONE OF THE RECONSTRUCTION LIGHT BEAMS FROM THE PLURALITY OF RECONSTRUCTION LIGHT SOURCES TO IRRADIATE THE SCREEN.”

At block S860, the reconstruction light beams may be received from the plurality of reconstruction light sources by a shutter, and one of the reconstruction light beams may be selectively passed through the shutter to irradiate the screen to reconstruct the holographic image of the object. For example, as illustrated in FIGS. 4 and 5, a shutter 412 may be configured to receive the reconstruction light beams from the plurality of reconstruction light sources 410a to 410n and selectively pass each of the received light beams in turn to provide a selected light beam L43. In case where light source unit 410 includes three color light sources, e.g., a red laser light source, a green laser light source, and a blue laser light source, shutter 412 may be sequentially switched to pass one of a red laser light, a green laser light and a blue laser light. Light beam L43 provided by shutter 412 may be transmitted to screen 460. When the holograms formed on screen 460 are irradiated with the reconstruction light beams L43, images of the object may be reconstructed.

In some embodiments, method 800 may be repeatedly performed for each reconstruction light beam selectively generated from the plurality of reconstruction light sources. For example, in case where the plurality of reconstruction light sources 410a to 410n includes three color light sources, e.g., a red laser light source, a green laser light source, and a blue laser light source, method 800 may be repeatedly performed to sequentially reconstruct red, green and blue holographic images. Also, the above-described operations of method 800 may be executed in a range from about 1 to 5 milliseconds.

One skilled in the art will appreciate that, for this and other methods disclosed herein, the functions performed in the methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

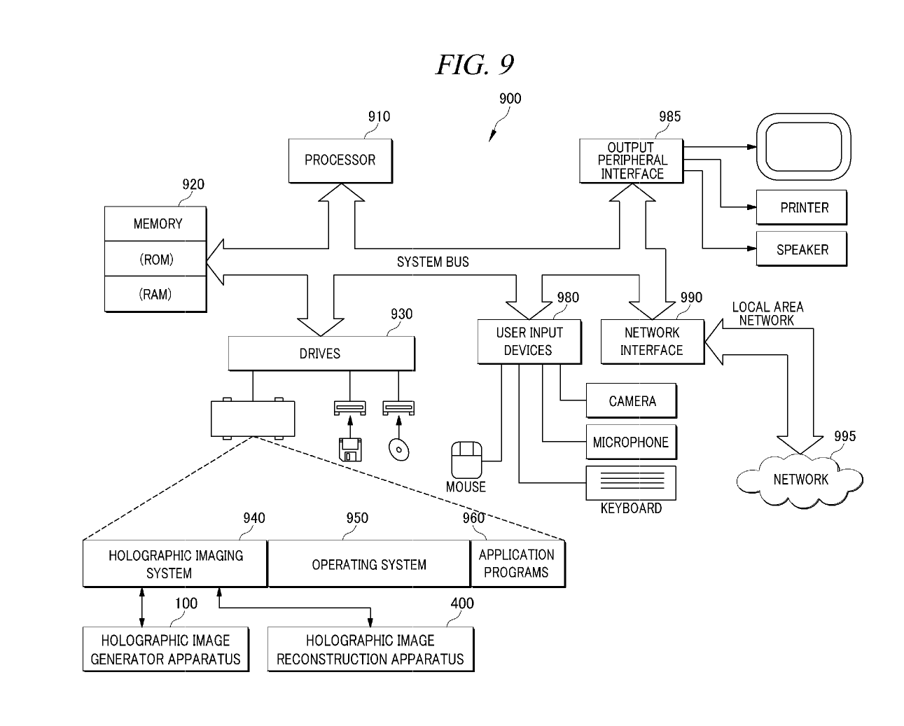

FIG. 9 shows a schematic block diagram illustrating an example computing system that can be configured to perform methods for generating and/or reconstructing a holographic image of an object, arranged in accordance with at least some embodiments described herein. As depicted in FIG. 9, a computer 900 may include a processor 910, a memory 920 and one or more drives 930. Computer 900 may be implemented as a conventional computer system, an embedded control computer, a laptop, or a server computer, a mobile device, a set-top box, a kiosk, a vehicular information system, a mobile telephone, a customized machine, or other hardware platform.

Drives 930 and their associated computer storage media may provide storage of computer readable instructions, data structures, program modules and other data for computer 900. Drives 930 may include a holographic imaging system 940, an operating system (OS) 950, and application programs 960. Holographic imaging system 940 may be adapted to control a holographic image generator apparatus 100, 200 or 310 and/or a holographic image reconstruction apparatus 350, 400 or 500 in such a manner as described above with respect to FIGS. 1 to 8.

Computer 900 may further include user input devices 980 through which a user may enter commands and data. Input devices can include an electronic digitizer, a camera, a microphone, a keyboard and pointing device, commonly referred to as a mouse, trackball or touch pad. Other input devices may include a joystick, game pad, satellite dish, scanner, or the like.

These and other input devices can be coupled to processor 910 through a user input interface that is coupled to a system bus, but may be coupled by other interface and bus structures, such as a parallel port, game port or a universal serial bus (USB). Computers such as computer 900 may also include other peripheral output devices such as display devices, which may be coupled through an output peripheral interface 985 or the like.

Computer 900 may operate in a networked environment using logical connections to one or more computers, such as a remote computer coupled to a network interface 990. The remote computer may be a personal computer, a server, a router, a network PC, a peer device or other common network node, and can include many or all of the elements described above relative to computer 900.

Networking environments are commonplace in offices, enterprise-wide area networks (WAN), local area networks (LAN), intranets, and the Internet. When used in a LAN or WLAN networking environment, computer 900 may be coupled to the LAN through network interface 990 or an adapter. When used in a WAN networking environment, computer 900 typically includes a modem or other means for establishing communications over the WAN, such as the Internet or a network 995. The WAN may include the Internet, the illustrated network 995, various other networks, or any combination thereof. It will be appreciated that other mechanisms of establishing a communications link, ring, mesh, bus, cloud, or network between the computers may be used.

In some embodiments, computer 900 may be coupled to a networking environment. Computer 900 may include one or more instances of a physical computer-readable storage medium or media associated with drives 930 or other storage devices. The system bus may enable processor 910 to read code and/or data to/from the computer-readable storage media. The media may represent an apparatus in the form of storage elements that are implemented using any suitable technology, including but not limited to semiconductors, magnetic materials, optical media, electrical storage, electrochemical storage, or any other such storage technology. The media may represent components associated with memory 1020, whether characterized as RAM, ROM, flash, or other types of volatile or nonvolatile memory technology. The media may also represent secondary storage, whether implemented as storage drives 930 or otherwise. Hard drive implementations may be characterized as solid state, or may include rotating media storing magnetically encoded information.

Processor 910 may be constructed from any number of transistors or other circuit elements, which may individually or collectively assume any number of states. More specifically, processor 910 may operate as a state machine or finite-state machine. Such a machine may be transformed to a second machine, or specific machine by loading executable instructions. These computer-executable instructions may transform processor 910 by specifying how processor 910 transitions between states, thereby transforming the transistors or other circuit elements constituting processor 910 from a first machine to a second machine. The states of either machine may also be transformed by receiving input from user input devices 980, network interface 990, other peripherals, other interfaces, or one or more users or other actors. Either machine may also transform states, or various physical characteristics of various output devices such as printers, speakers, video displays, or otherwise.

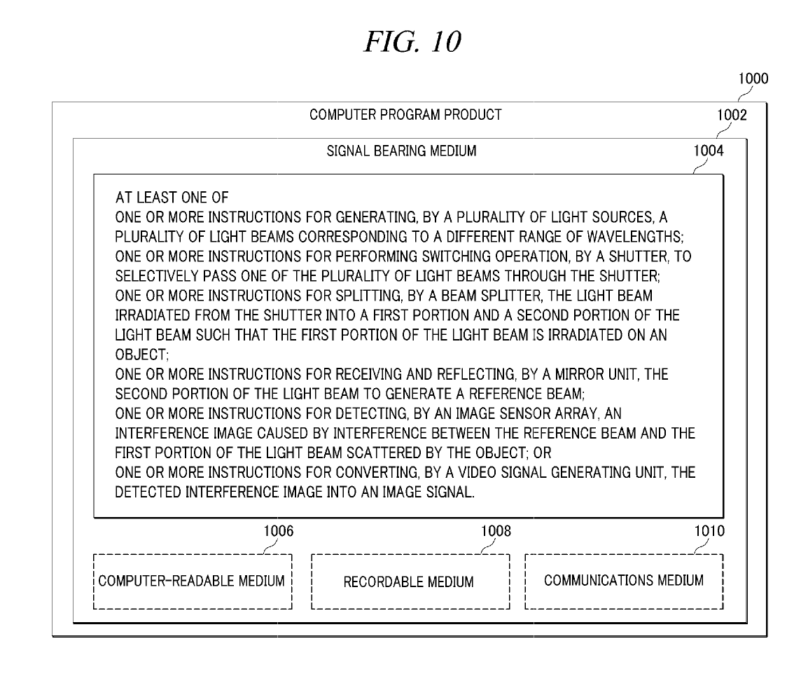

FIG. 10 illustrates computer program products that can be utilized to generate a holographic image of an object, arranged in accordance with at least some embodiments described herein. Program product 1000 may include a signal bearing medium 1002. Signal bearing medium 1002 may include one or more instructions 1004 that, when executed by, for example, a processor, may provide the functionality described above with respect to FIGS. 1 to 8. By way of example, instructions 1004 may include: one or more instructions for generating, by a plurality of light sources, a plurality of light beams corresponding to a different range of wavelengths; one or more instructions for performing switching operation, by a shutter, to selectively pass one of the plurality of light beams through the shutter, one or more instructions for splitting, by a beam splitter, the light beam irradiated from the shutter into a first portion and a second portion of the light beam such that the first portion of the light beam is irradiated on an object; one or more instructions for receiving and reflecting, by a mirror unit, the second portion of the light beam to generate a reference beam; one or more instructions for detecting, by an image sensor array, an interference image caused by interference between the reference beam and the first portion of the light beam scattered by the object; or one or more instructions for converting, by a video signal generator unit, the detected interference image into an image signal. Thus, for example, referring to FIGS. 1 and 2, holographic image generator apparatus 100 or 200 may undertake one or more of the blocks shown in FIG. 7 in response to instructions 1004.

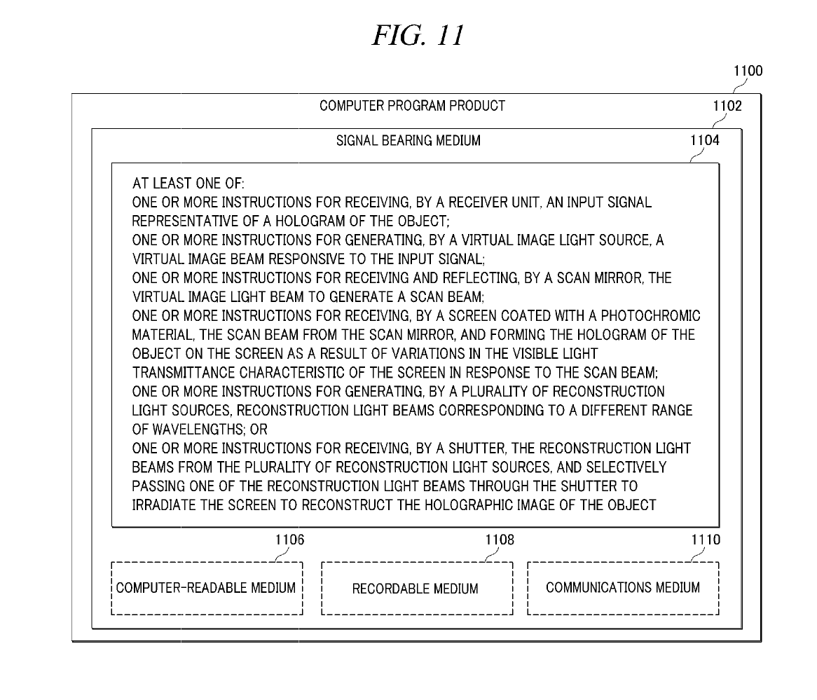

FIG. 11 illustrates computer program products that can be utilized to reconstruct a holographic image of an object, arranged in accordance with at least some embodiments described herein. Program product 1100 may include a signal bearing medium 1102. Signal bearing medium 1102 may include one or more instructions 1104 that, when executed by, for example, a processor, may provide the functionality described above with respect to FIGS. 1 to 8. By way of example, instructions 1104 may include at least one of: one or more instructions for receiving, by a receiver unit, an input signal representative of a hologram of the object; one or more instructions for generating, by a virtual image light source, a virtual image beam responsive to the input signal; one or more instructions for receiving and reflecting, by a scan mirror, the virtual image light beam to generate a scan beam; one or more instructions for receiving, by a screen coated with a photochromic material, the scan beam from the scan mirror, and forming the hologram of the object on the screen as a result of variations in the visible light transmittance characteristic of the screen in response to the scan beam; one or more instructions for generating, by a plurality of reconstruction light sources, reconstruction light beams corresponding to a different range of wavelengths; or one or more instructions for receiving, by a shutter, the reconstruction light beams from the plurality of reconstruction light sources, and selectively passing one of the reconstruction light beams through the shutter to irradiate the screen to reconstruct the holographic image of the object. Thus, for example, referring to FIGS. 4 and 5, holographic image reconstruction apparatus 400 or 500 may undertake one or more of the blocks shown in FIG. 8 in response to instructions 1104.

In some implementations, signal bearing medium 1002 or 1102 may encompass a computer-readable medium 1006 or 1106, such as, but not limited to, a hard disk drive, a Compact Disc (CD), a Digital Video Disk (DVD), a digital tape, memory, etc. In some implementations, signal bearing medium 1002 or 1102 may encompass a recordable medium 1008 or 1108, such as, but not limited to, memory, read/write (R/W) CDs, R/W DVDs, etc. In some implementations, signal bearing medium 1002 or 1102 may encompass a communications medium 1010 or 1110, such as, but not limited to, a digital and/or an analog communication medium (e.g., a fiber optic cable, a waveguide, a wired communications link, a wireless communication link, etc.). Thus, for example, program product 1000 or 1100 may be conveyed to one or more modules of holographic image generator apparatus 100 or 200 or holographic image reconstruction apparatus 400 or 500 by an RF signal bearing medium 1002 or 1102, where the signal bearing medium 1002 or 1102 is conveyed by a wireless communications medium 1010 or 1110 (e.g., a wireless communications medium conforming with the IEEE 802.11 standard).

The present disclosure is not to be limited in terms of the particular embodiments described in this application, which are intended as illustrations of various aspects. Many modifications and variations may be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

The herein described subject matter sometimes illustrates different components contained within, or connected with, different other components. It is to be understood that such depicted architectures are merely examples, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. An apparatus configured to generate a holographic image of an object, the apparatus comprising:
a plurality of light sources, each configured to generate a light beam corresponding to a wavelength in a different range;
a shutter configured to receive the light beams from the plurality of light sources and selectively pass each of the received light beams in turn to provide a selected light beam;
a beam splitter configured to split the selected light beam into a first light beam and a second light beam, wherein the beam splitter is also configured to irradiate the first light beam on the object such that at least part of the first light beam is scattered by the object to generate an object light beam;
a mirror unit configured to receive the second light beam from the beam splitter, and return at least part of the second light beam as a reference light beam;
an image sensor array configured to receive the reference light beam and the object light beam, and also configured to detect an image of interference caused by the reference light beam and the object light beam, wherein the image sensor array comprises an array of sensors configured in a shape of either a cylinder or a polygonal prism that substantially surrounds the object; and
a video signal generator unit configured to convert the detected image into an image signal associated with each of the plurality of light sources.

2. The apparatus of claim 1, further comprising a video signal recorder unit configured to record the image signal in a storage unit.

3. The apparatus of claim 1, further comprising a video signal transmitter unit configured to transmit the image signal to a holographic image reconstruction apparatus.

4. The apparatus of claim 1, wherein the image sensor array comprises a charge coupled device (CCD) array.

5. The apparatus of claim 1, wherein the image sensor array comprises a two-dimensional sensor array.

6. (canceled)

7. The apparatus of claim 1, wherein the beam splitter comprises an aluminum layer formed on a glass substrate.

8. The apparatus of claim 1, wherein the plurality of light sources comprises a red laser light source, a green laser light source, and a blue laser light source.

9. The apparatus of claim 1, further comprising a controller configured to control operation of one or more of the shutter and the video signal generator unit.

10. The apparatus of claim 9, wherein the controller is configured to store a control program to control operation of the apparatus.

11. An apparatus configured to reconstruct a holographic image of an object, the apparatus comprising:
a receiver unit configured to receive an input signal representative of a hologram of the object;
a virtual image light source configured to generate a virtual image light beam responsive to the input signal;
a scan mirror configured to receive the virtual image light beam and return the virtual image light beam as a scan beam, wherein the scan mirror is configured to be magnetically actuated, electrically actuated or electromagnetically actuated;
a screen coated with a photochromic material and configured to receive the scan beam from the scan mirror, wherein the screen includes a visible light transmittance characteristic that is adjustable in response to the scan beam and effective to form the hologram of the object on the screen, and wherein the photochromic material comprises hexaarylbiimidazole (HABI);
a plurality of reconstruction light sources, each configured to generate a reconstruction light beam corresponding to a wavelength in a different range; and
a shutter configured to receive the reconstruction light beams from the plurality of reconstruction light sources, and selectively pass one of the reconstruction light beams through the shutter to irradiate the screen to reconstruct the holographic image of the object.

12. The apparatus of claim 11, wherein the screen comprises the photochromic material formed on a transparent layer.

13. The apparatus of claim 12, wherein the transparent layer comprises a quartz glass material or a borosilicate glass material.

14. The apparatus of claim 12, wherein the transparent layer comprises a transparent plastic material or polyethylene terephthalate (PET) material.

15. The apparatus of claim 12, wherein the photochromic material comprises one or more materials selected from the group that includes potassium tantalate (KTaO₃) doped with an impurity and/or strontium titanate (SrTiO₃) doped with an impurity.

16. The apparatus of claim 15, wherein the impurity comprises nickel (Ni) and iron (Fe).

17. (canceled)

18. The apparatus of claim 11, wherein the screen is configured in a shape of a two-dimensional panel, a cylinder or a polygonal prism.

19. The apparatus of claim 11, wherein the receiver unit is configured to receive the input signal from a holographic image generator apparatus.

20. The apparatus of claim 11, wherein the virtual image light source is configured to generate an ultraviolet laser beam or an electron beam as the virtual image light beam.

21. The apparatus of claim 11, wherein the plurality of reconstruction light sources comprises a red laser light source, a green laser light source, and a blue laser light source.

22. (canceled)

23. A method to generate and reconstruct a holographic image of an object, the method comprising:
generating, by a plurality of light sources, a plurality of light beams corresponding to a different range of wavelengths, wherein the plurality of light beams includes reconstruction light beams;
receiving the plurality of light beams from the plurality of light sources at a shutter;
performing switching operation, by the shutter, to selectively pass one of the plurality of light beams through the shutter;
splitting, by a beam splitter, the light beam irradiated from the shutter into a first portion and a second portion of the light beam such that the first portion of the light beam is irradiated on the object to reconstruct a holographic image of the object, wherein the beam splitter comprises an aluminum layer formed on a glass substrate;
receiving and returning, by a mirror unit, the second portion of the light beam as a reference beam;
detecting, by an image sensor array, an interference image caused by interference between the reference beam and the first portion of the light beam scattered by the object, wherein the image sensor array comprises an array of sensors configured in a shape of either a cylinder or a polygonal prism that substantially surrounds the object; and
converting, by a video signal generator unit, the detected interference image into an image signal.

24. The method of claim 23, further comprising recording, by a video signal recorder unit, the image signal in a storage unit.

25. The method of claim 23, further comprising transmitting, by a video signal transmitter unit, the image signal to a holographic image reconstruction apparatus.

26. The method of claim 23, wherein the method is repeatedly performed, and a period of each repetition of the method is in a range from about 1 to 5 milliseconds.

27.-34. (canceled)
